(19) United States
(12) Patent Application Publication
(10) Pub. No.: US 2007/0097755 A1
(43) Pub. Date: May 3, 2007

(54) Method for comparing a first data set with a second data set

(76) Inventors: Raj Narayan Marndi, Bangalore (IN); Maheedhar Panchalamarr Venkat, Bangalore (IN); Sachin Daniel Commen, Bangalore (IN)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 11/491,753

(22) Filed: Jul. 24, 2006

(30) Foreign Application Priority Data
Oct. 27, 2005 (IN) IN2875/DEL/2005

(51) Int. Cl. G11C 7/06

(52) U.S. Cl. 365/189.07

(57) ABSTRACT

A method for comparing a first data set with a second data set, where each comprises one or more corresponding segments. The method comprises determining the difference between corresponding pairs of end points of corresponding segments, and deeming the first data set to match the second data set if the difference is less than a predetermined tolerance for all of the corresponding pairs of end points, and deeming the first data set not to match the second data set if the difference is greater than the predetermined tolerance for any one of the corresponding pairs of end points.

### BACKGROUND OF THE PRESENT INVENTION

Pattern matching in computing applications involves locating instances of a shorter sequence (such as a string)—or an approximation thereof—within an equal or larger sequence. This is particularly useful in the analysis of time series data, such as for data mining.

Various pattern matching algorithms exist, each suitable for specific applications.

### BRIEF DESCRIPTION OF THE DRAWINGS

Embodiments of the invention will now be described by way of example only with reference to the drawings in which:

FIGS. 1A and 1B depict a flow diagram of a time series query method according to an exemplary embodiment;

FIG. 2 is a schematic plot of segmentation of reference data according to the exemplary embodiment of FIGS. 1A and 1B;

FIG. 3 is a schematic plot of the identification of local maxima and minima in the input pattern and the current time window of the reference data according to the exemplary embodiment of FIGS. 1A and 1B;

FIG. 4 is a schematic plot of sub-segmentation of an input pattern and reference data according to the exemplary embodiment of FIGS. 1A and 1B;

FIG. 5 is a schematic plot of the translation of a mismatched input pattern relative to reference data according to the exemplary embodiment of FIGS. 1A and 1B;

FIG. 6 is a schematic view of a data storage medium.

### DETAILED DESCRIPTION OF EXEMPLARY EMBODIMENTS

There will be described a method for comparing a first data set with a second data set, each comprising one or more corresponding segments. The method comprises determining the difference between corresponding pairs of end points of corresponding segments, and deeming the first data set to match the second data set if the difference is less than a predetermined tolerance for all of the corresponding pairs of end points, and deeming the first data set not to match the second data set if the difference is greater than the predetermined tolerance for any one of the corresponding pairs of end points. If the difference between a corresponding pairs of end points equals the predetermined tolerance, the method may either include treating this as consistent with matching or as inconsistent with matching, according to user preference, application or otherwise.

The method may include determining the difference for all of the end points of the segments, then identifying whether the. difference exceeds the predetermined tolerance for any of the end points of the segments. Thus, the difference may be determined for all the segments (and both ends thereof) before checking whether any difference value exceeds the tolerance (hence indicative of a mismatch) or whether all the difference values are less than the tolerance (hence indicative of a match).

The method may comprise determining the difference until either the difference has been determined to be less than the predetermined tolerance for all of the corresponding pairs of end points or the difference has been determined to be greater than the predetermined tolerance for any one of the corresponding pairs of end points. Thus, rather than determining the difference for every pairs of end points then checking against the tolerance, the determination of differences can stop after any single pair of end points is found to exceed the tolerance.

The method may include identifying a maximum and a minimum value in each of segments of the first data set and of the second data set, performing a comparison of the maxima of the pairs of corresponding segments, the minima of the pairs of corresponding segments, or both the maxima of the pairs of corresponding segments and the minima of the pairs of corresponding segments, and deeming the first data set not to match the second data set if a mismatch is identified.

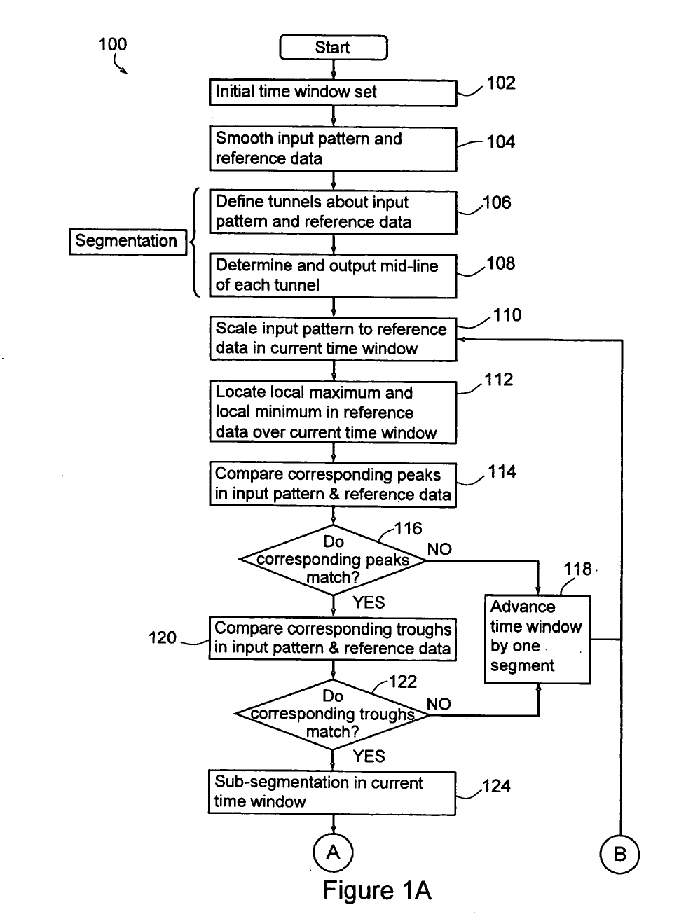

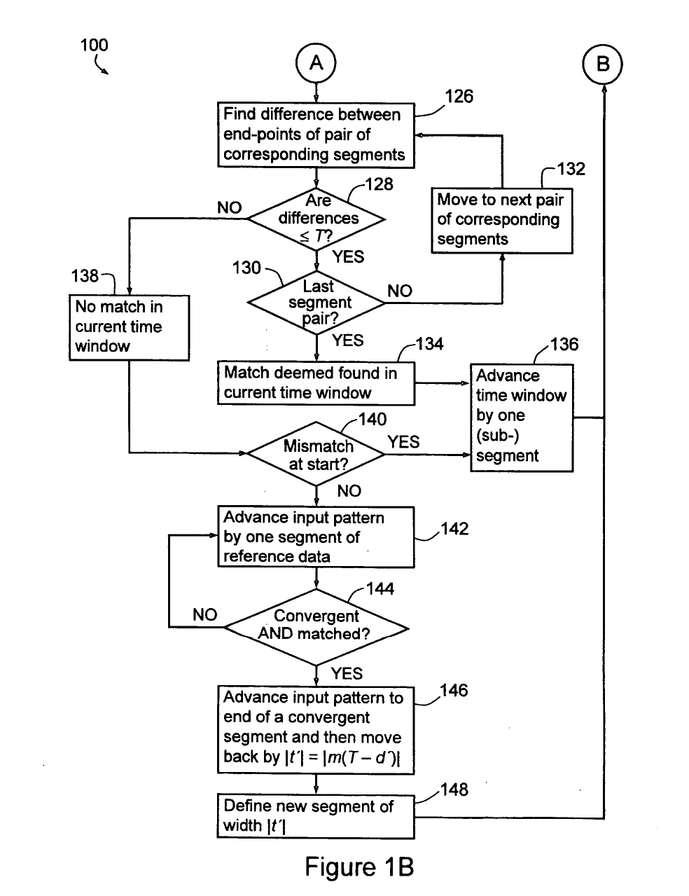

A time series query method for analysing time series data (referred to below as reference data) is illustrated by means of a flow diagram in FIGS. 1A and 1B at 100. The method provides a fast and efficient approximate pattern matching algorithm for matching an input pattern to time series reference. In the flow diagram of FIGS. 1A and 1B, steps 102 to 124 are regarded as preprocessing of the reference data, while pattern matching proper is performed in steps 126 to 134.

Thus, at step 102 (see FIG. 1A), an initial time window is set. This generally extends from the lowest time value in the reference data to a time value equal to the time length of the input pattern.

At step 104, the input pattern and the reference data set are smoothed to eliminate minor fluctuations in the data that are regarded as noise. Thus, in the case of the reference data, a window is defined about each reference data point, the average value over that slide window is determined, and that average value is used as the new value of that respective point, thereby reducing such fluctuations. The input pattern is processed in the same manner.

The size of the window defined about each data point dictates how much proximity is acceptable, and is specified by the user. Some users may wish to identify only regions of high similarity between the reference data and the input pattern, and will therefore employ a small window size. Users content to locate less close matches will employ a larger window size.

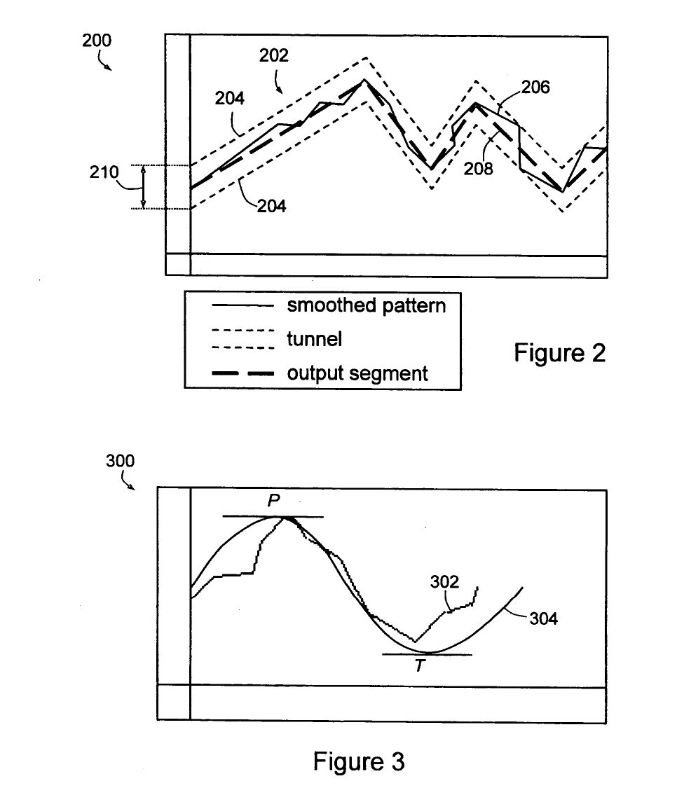

At steps 106 and 108, segmentation is performed in order to reduce the number of comparison points so that matching is faster. Thus, referring to FIG. 2, at step 106 a “tunnel” 202 with parallel sides 204 (shown as dashed lines) and a predetermined width is fitted to and encases a segment of the smoothed, referenced data 206. Similarly, a tunnel (not shown) with parallel sides and a predetermined width is fitted to and encases a segment of the smoothed, input pattern (not shown).

At step 108 the mid-line 208 of the tunnel 202 that was fitted to the referenced data 206 is determined and output as an output segment for use in place of the smoothed, referenced pattern 204. (The mid-line 208 is also stored for future use.) Similarly, the mid-line of the tunnel fitted to the input pattern is determined and output as an output segment for use in place of the smoothed, referenced pattern 204; this mid-line can—but will generally not—be stored for future use.

The width of the tunnel is, in each case, specified by the user. It equals the vertical distance 210 between the top of the tunnel and the bottom of the tunnel. Its width is chosen according to the level of matching desired between the reference data and the input pattern. Thus, the smaller the width of the tunnel, the more closely must the reference data match the input pattern if a match is to be deemed to exist during the subsequent pattern matching proper.

At step 110, the input pattern is scaled to the reference data in the current time window. This is done because comparisons of two patterns (i.e. data sets) have little meaning if the absolute scales of the data differ significantly. Hence at this step the input pattern is scaled by multiplying each point such that its average becomes equal to the sliding average of the reference data.

At step 112, the local maximum (or peak) and local minimum (or trough) in the input pattern (denoted Pᵢ and Tᵢ respectively) and, similarly, the local maximum and local minimum in the reference data (denoted Pᵣ and Tᵣ respectively) are located for the current (initially, first) time window. This is illustrated schematically in FIG. 3, which is a plot 300 of what may be regarded as either an input pattern or reference data 302 in an exemplary time window. As shown in FIG. 3, every pattern can be viewed as an approximation of a sinusoidal curve 304, which has only one point as local maximum P and one point as local minimum T over a period. Every other point has at least another point in that cycle with the same amplitude or height different between peak and trough. These maxima and minima in the data are identified so that, when subsequently comparing a point-pair, a comparison can be made between the peaks and troughs of the input pattern and the reference data. If any of them is found to be mismatched, then—as is described below—the method can immediately advance by one segment.

These properties of each cycle of a sinusoidal curve (i.e. only one peak and one trough, and every other point having at least one other point with the same amplitude) means that it is quicker, when comparing sinusoidal curves, to find a mismatch than to find a match (which requires an exhaustive point by point comparison). Further, since the number of peaks and troughs are minimal, there exists a great probability of mismatching these points if a mismatch is indeed to be found. Hence, by representing both data sets as sinusoidal curves, mismatches can be located promptly.

Thus, by initially comparing the peaks and troughs of both the input and referenced patterns, many mismatches can be quickly identified in this phase, which leads to faster jumps and hence faster matching. If all the peaks and troughs are found to match, then matching need only be further checked in respect of sub-segment end-points.

Hence, at step 114 the method compares corresponding peaks (or maxima) in the input pattern and reference data and, at step 116, test whether the corresponding peaks match. If they do not match, the time window is advanced by one segment at step 118 and processing returns to step 110. If a match is found at step 116, processing continues at step 120 where corresponding troughs (or minima) in the input pattern and reference data are compared. At step 122, the method tests whether these corresponding troughs match; if not, processing continues at step 118 where the time window is advanced by one segment and then returns to step 110.

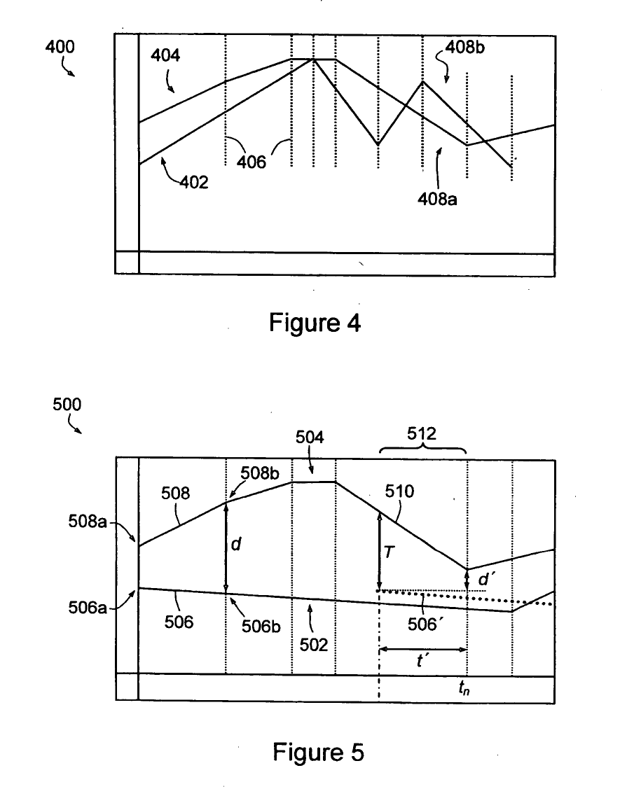

If the corresponding troughs are found to match at step 122, processing continues at step 124, where sub-segmentation is performed in the current time window. Referring to the schematic plot of an exemplary time window 400 of FIG. 4, in which the horizontal axis represents time increasing to the right, both the segmented input pattern 402 (of initially l=4 segments) and the segmented reference data 404 (of initially k=5 segments) are divided into a plurality of segments with common end-points defined by the union of the sets of end-points of the original l and k segments, as illustrated in FIG. 4. After this step, therefore, both the segmented input pattern 402 and the segmented reference data 404 will typically both be divided into l+k segments (unless some of the original l and k segments were initially coincident), as indicated in FIG. 4 by means of vertical dotted lines 406. As a result, each (now often smaller) segment or sub-segment in one pattern has a corresponding segment in the other pattern, where “corresponding means that they share the same start and end values on the time (i.e. horizontal) axis.

Once the sub-segmentation has been completed, the actual pattern matching is performed. This involves the following steps 126 to 134.

At step 126 (see FIG. 1B), the differences between corresponding segment end-points are determined. That is, for a segment of the input pattern 402 and the corresponding segment of the reference data 404 (such as sub-segments 408a and 408b respectively), the difference between the start values (at the left end of these segments in FIG. 4) is calculated, as is the difference between the end values.

At step 128, the method checks whether, for this pair of segments, the differences between the end-points are both less than or equal to a tolerance T, that is, whether this pair of corresponding segments match to within that tolerance. If so, processing passes to step 130, where the method checks whether the segment pair just compared at steps 126 and 128 was the last pair of corresponding segments in the current time window. If not, the method continues at step 132 where it advances to the next pair of corresponding segments in the current time window, then returns to step 126. Progressively, therefore, all the pairs of corresponding segments in the current time window are compared as long as no mismatches are found.

If, at step 130, it is determined that the last segment pair has just been compared, the method continues at step 134, where a match is held to have been found, and the input pattern 402 is considered to match the reference data 404 in that time window. Processing then continues at step 136, where the current time window is advanced by the width of the lowest segment (that is, the lowest sub-segment defined at step 124), and the method then continues at step 122.

If, at step 128, the method determines that, for the instant pair of segments, the difference between either pair of end-points is greater than the tolerance T, the input pattern 402 and the reference data 404 are considered not to match in that time window and the method continues at step 138, where a match is held not to have been found.

In this embodiment at steps 126 to 132, the pairs of corresponding segments are compared from left to right as shown in FIG. 4 (i.e. in order of increasing time), but it will be appreciated that the order in which the pairs of corresponding segments are compared may be reversed or otherwise varied from this scheme if desired. Furthermore, in an alternative embodiment, step 126 is performed for all pairs of corresponding segments before step 128. However, this will generally increase computing time, as many of the iterations of step 126 will be redundant once a single mismatch occurs.

In addition, it will be appreciated by those in the art that it is sufficient to compare only the end-points of the segments to determine whether corresponding segments match because, if the end-points of the segments match according to this test, then all the points in the segment necessarily match. Thus, the criterion for finding a match may be described as requiring that all the points in all the segments match, but according to this embodiment, this is established by comparing only end-points. In a computing environment this considerably reduces computing time overhead.

From step 138 (i.e. a match is held not to have been found in the current time window), the method continues at step 140. At this step, the method of this embodiment determines whether the input pattern 402 and the reference data 404 were held not to match owing to a mismatch at the start of a pair of corresponding segments or at the end of those corresponding segments.

If the mismatched segments were mismatched at their starts, the method continues at step 136, at which—as described above—the current time window is advanced by the width of its lowest (sub-)segment and the method then continues at step 122.

If the mismatched segments were not mismatched at their start points but were at their end points, the method continues at step 142. Clearly, if the corresponding segments that were held not to match were not mismatched at their start points but were at their end points they must be diverging in the increasing time direction. Such a situation is depicted in FIG. 5, which is a schematic plot 500 of an input pattern 502 and reference data 504. The horizontal axis again represents time, increasing to the right. Segment 506 of input pattern 502 and segment 508 of reference data 504 are mismatched because, although their start points 506a and 508a respectively are matched (differing by less than T), their end points 506b and 508b respectively differ by d>T.

Thus, at step 142 the method advances in an increasing time direction by one segment. At step 144, the method determines whether the instant corresponding segments (i.e. of the input pattern and of the reference data) converge and whether the start point 506a of the entire input pattern is within tolerance T of the end point of the instant segment of the reference data. In the example of FIG. 5, these conditions hold at time tₙ, where the start point 506a of the input pattern and the end point of the instant segment 510 of the reference data 504 differ by d′<T. (Convergence is defined to obtain when the difference between the end points is less than the difference between the start points.)

If either or both these conditions are not satisfied, the method returns to step 142. If both these conditions are satisfied, -the method continues at step 146, at which the input pattern is advanced in a time increasing direction to the end point of the segment (510 in FIG. 5) where these conditions were found to be satisfied, then reversed by an amount |t′| such that the start point of the input pattern differs from the reference data by the tolerance T.

Hence, in the example shown in FIG. 5, t′=m(T−d′), where m is the gradient of the reference data in the instant segment, and the input pattern is translated in the decreasing time direction (i.e. leftwards in FIG. 5). In the example shown in FIG. 5, the gradient of the converging portion 510 of the reference data is negative, so t′ is negative (since by definition d′<T). Hence, the backward component of step 146 can be described either as advancing by t′ or as moving backward by |t′|=−t′. In some instances, however, this gradient may be positive (such as if the input pattern is greater than the reference data at all points in the current time window), in which case the backward component of step 146 could be described as advancing by −t′ or moving backward by |t′|=t′. In general, therefore, this movement is described as moving backward by |t′|.

Thus, by advancing the input pattern (502 in FIG. 5) in this manner, only mismatched points of the input pattern are compared with the reference data (504 in FIG. 5), to minimize the number of comparisons that need be performed.

Next, at step 148 a new segment 512 of width |t′| is defined, extending from the time translated start point of the input pattern to the end point of the reference data segment (510 in FIG. 5) where these conditions were found to be satisfied. Processing then continues at step 122.

### EXAMPLE

Reference data (in the form of Hewlett-Packard stock indices over 5 years) was searched for matches with input patterns of various lengths, using both the technique described in Keogh and Smyth (A probabilistic approach to fast pattern matching in time series databases, Proc. of the 3rd International Conference of Knowledge Discovery and Data Mining (1997) 24-30)and that of this embodiment. The number of comparisons that were made in each case are tabulated in Table 1. This table also includes the percentage improvement in the number of comparisons by employing the method of this embodiment. This percentage improvement was calculated as:
% improvement=(M−N)×100/N

where M is the number of comparisons required according to the method of Keogh and Smyth and N is the number of comparisons required according to the method of this embodiment.

TABLE 1
Number of comparisons required in pattern matching performed by
comparative method [6] and method of present embodiment

| | Length | | | | |
|---|---|---|---|---|---|
| | 10 | 20 | 30 | 40 | 50 |
| M (comparative) | 882 | 1616 | 2551 | 4701 | 8908 |
| N (invention) | 202 | 232 | 275 | 325 | 383 |
| % Improvement | 323 | 587 | 823 | 1344 | 2223 |

From the results in Table 1, it can be seen that the method of this embodiment provides better results than that of Keogh and Smyth. Further, it will be observed that the improvement increases with the length of the input pattern.

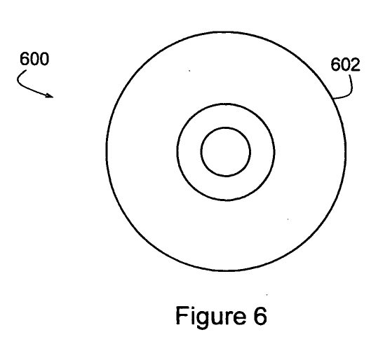

Referring to FIG. 6, in another embodiment 600 the necessary software for implementing the method of FIGS. 1A and 1B is provided on a data storage medium in the form of CD-ROM 602. CD-ROM 602 contains program instructions for implementing the method of FIGS. 1A and 1B. It will be understood that, in this embodiment, the particular type of data storage medium may be selected according to need or other requirements. For example, instead of CD-ROM 602 the data storage medium could be in the form of a magnetic medium, but essentially any data storage medium will suffice.

The foregoing description of the exemplary embodiments is provided to enable any person skilled in the art to make or use the present technique. While the present technique has been described with respect to particular illustrated embodiments, various modifications to these embodiments will readily be apparent to those skilled in the art, and the generic principles defined herein may be applied to other embodiments without departing from the spirit or scope of the disclosure. It is therefore desired that the present embodiments be considered in all respects as illustrative and not restrictive. Accordingly, the present invention is not intended to be limited to the embodiments described above but is to be accorded the widest scope consistent with the principles and novel features disclosed herein.

1. A method for comparing a first data set with a second data set, each comprising one or more corresponding segments, said method comprising:
determining the difference between corresponding pairs of end points of corresponding segments; and
deeming said first data set to match said second data set if said difference is less than a predetermined tolerance for all of said corresponding pairs of end points, and deeming said first data set not to match said second data set if said difference is greater than said predetermined tolerance for any one of said corresponding pairs of end points.

2. A method as claimed in claim 1, including determining said difference for all of said end points of said segments, then identifying whether said difference exceeds said predetermined tolerance for any of said end points of said segments.

3. A method as claimed in claim 1, including determining said difference until either said difference has been determined to be less than said predetermined tolerance for all of said corresponding pairs of end points or said difference has been determined to be greater than said predetermined tolerance for any one of said corresponding pairs of end points.

4. A method as claimed in claim 1, including identifying a maximum and a minimum value in each of segments of said first data set and of said second data set, performing a comparison of said maxima of said pairs of corresponding segments, said minima of said pairs of corresponding segments, or both said maxima of said pairs of corresponding segments and said minima of said pairs of corresponding segments, and deeming said first data set not to match said second data set if a mismatch is identified.

5. A method as claimed in claim 4, including ceasing said. comparison once a mismatch in either said maxima or said minima is identified.

6. A method as claimed in claim 1, including, if a mismatch is identified, advancing said first data set relative to said second data set by an integral number of segments until a first segment of said first data set is convergent with a segment of said second data set and a start point of said first segment differs from an end point of said corresponding segment by less than said predetermined tolerance, then reversed until said start point of said first segment differs from said second data set by said predetermined tolerance.

7. A computer readable medium provided with program data that, when executed on a computing system, implements the method of claim 1.

8. A computer provided with program data that, when executed, implements the method of claim 1.

9. A method of processing a sequence query, comprising:
specifying first and second sequences;
segmenting said first and second sequences so that said first and second sequences comprise a plurality of corresponding segments;
determining the difference between corresponding pairs of end points of corresponding segments; and
deeming said first sequence to match said second sequence if said difference is less than a predetermined tolerance for all of said corresponding pairs of end point's, and deeming said first sequence not to match said second sequence if said difference is greater than said predetermined tolerance for any one of said corresponding pairs of end points.

10. A computer readable medium provided with program data that, when executed on a computing system, implements the method of claim 8.
